(19) United States
(12) Patent Application Publication
(10) Pub. No.: US 2010/0140786 A1
(43) Pub. Date: Jun. 10, 2010

(54) SEMICONDUCTOR POWER MODULE PACKAGE HAVING EXTERNAL BONDING AREA

(75) Inventors: Keun-hyuk LEE, Bucheon-si (KR); Young-sun KO, Incheon (KR); Seung-won LIM, Bucheon-si (KR); Man-kyo JUNG, Bucheon-si (KR); Seung-yong CHOI, Seoul (KR)

Correspondence Address: CANTOR COLBURN, LLP, 20 Church Street, 22nd Floor, Hartford, CT, 06103, US

(73) Assignee: FAIRCHILD KOREA SEMICONDUCTOR LTD., Bucheon-si (KR)

(21) Appl. No.: 12/632,298

(22) Filed: Dec. 7, 2009

(30) Foreign Application Priority Data
Dec. 5, 2008 (KR) 10-2008-0123150

(51) Int. Cl. H01L 23/498

(52) U.S. Cl. 257/693; 257/690; 257/E23.06; 257/E23.07

(57) ABSTRACT

Provided is a semiconductor power module package including a bonding area on a direct bonding cupper (DBC) board. The semiconductor power module package includes: one or more semiconductor chips; a sealing member sealing the one or more semiconductor chips; a plurality of leads electrically connected to the one or more semiconductor chips and exposed from the sealing member; and an external bonding member electrically connected to the one or more semiconductor chips and electrically connecting an external circuit board exposed from the sealing member.

### CROSS-REFERENCE TO RELATED PATENT APPLICATION

This application claims the benefit of Korean Patent Application No. 10-2008-0123150, filed on Dec. 5, 2008, in the Korean Intellectual Property Office, the disclosure of which is incorporated herein in its entirety by reference.

### BACKGROUND OF THE INVENTION

1. Field of the Invention

The present invention relates to a semiconductor power module package, and more particularly, to a semiconductor power module package in which an external bonding area is disposed in a direct bonding cupper (DBC) substrate.

2. Description of the Related Art

In a semiconductor power module package, a semiconductor chip is attached onto a lead frame and is sealed by using a molding material. The more highly the semiconductor chip is integrated, the more the semiconductor power module package requires bonding pads used to externally connect the semiconductor chip, so that the lead number of the lead frame and the size of the semiconductor package increase. The semiconductor power module package connects leads to an external circuit board by a soldering and wire bonding process.

The semiconductor power module package requires an additional soldering and wire bonding area in the lead frame, which increases the package size. Also, soldered leads are vulnerable to a physical vibration or a solder crack.

### SUMMARY OF THE INVENTION

The present invention provides a semiconductor power module package including an external bonding area that is wire bonded to an external circuit substrate.

According to an aspect of the present invention, there is provided a semiconductor power module package. The semiconductor power module package includes one or more semiconductor chips and a sealing member sealing the one or more semiconductor chips. A plurality of leads is electrically connected to the one or more semiconductor chips and is exposed from the sealing member. An external bonding member is electrically connected to the one or more semiconductor chips and is electrically connecting an external circuit board exposed from the sealing member.

The semiconductor power module package may further include: a packaging substrate including electrically separated conductive film patterns. First conductive film patterns of the conductive film patterns may be electrically connected to the plurality of leads. The first and second conductive film patterns may include a Cu film plated with one selected from a group consisting of Ni, Au, or Ag and a bare Cu film.

The external bonding member may include a plurality of external bonding areas for wire-bonding to the external circuit board and be disposed on the packaging substrate and exposed from the sealing member. The plurality of external bonding areas may include the portions of second conductive film patterns of the conductive film patterns exposed from the sealing member. A plurality of power signals may be provided to the one or more semiconductor chips via the plurality of leads, and a plurality of control signals may be provided to the one or more semiconductor chips via the plurality of external bonding areas.

The plurality of external bonding areas may include a plurality of external bonding leads that are partially exposed from the sealing member. The plurality of leads and the plurality of external bonding leads may include one selected from a group consisting of Ni plated Cu leads, P containing Ni plated Cu leads, Ag plated Cu leads, or bare Cu leads.

The external bonding member may further include a plurality of external bumps disposed on the plurality of external bonding leads exposed from the sealing member. The plurality of external bumps may include Al bumps. The plurality of leads may include power leads, and the plurality of external bonding leads may include signal leads.

The one or more semiconductor chips may be disposed on some of the first conductive film patterns. The packaging substrate may include a direct bonding cupper (DBC) substrate. The sealing member may include a transfer molded epoxy molding compound (EMC).

The external bonding member may be wire-bonded to the external circuit board by an external wire. The external wire may include one selected from a group consisting of an Al wire, an Ag wire, and a Cu wire.

According to another aspect of the present invention, there is provided a semiconductor power module package. The semiconductor power module package includes an insulation substrate including one or more electrically separated conductive film patterns; a plurality of semiconductor chips on a plurality of first conductive film patterns of the one or more conductive film patterns; a sealing member formed on the upper and side surfaces of the insulation substrate and sealing the plurality of semiconductor chips and the one or more conductive film patterns; and a plurality of leads electrically connected to the plurality of semiconductor chips and exposed from the sealing member, wherein a plurality of second conductive film patterns of the conductive film patterns that are not disposed on the plurality of semiconductor chips include a plurality of external bonding areas that are electrically connected to an external circuit board and is exposed from the sealing member.

The plurality of leads may include power leads, wherein the plurality of external bonding areas are electrically connected to the external circuit board by an external wire, and transfer signals between the plurality of semiconductor chips and the external circuit board.

### BRIEF DESCRIPTION OF THE DRAWINGS

The above and other features and advantages of the present invention will become more apparent by describing in detail exemplary embodiments thereof with reference to the attached drawings in which:

FIG. 1A is a plan view of a semiconductor power module package including an external boding area according to an embodiment of the present invention;

FIG. 1B is a plan view of the semiconductor power module package shown in FIG. 1A before being molded;

FIG. 1C is a cross-sectional view of the semiconductor power module package shown in FIG. 1A taken from along a line IC-IC;

FIG. 1D is a cross-sectional view of the semiconductor power module package shown in FIG. 1C in which the external boding area is wire-bonded by an external wire;

FIG. 2A is a plan view of a semiconductor power module package including an external boding area according to another embodiment of the present invention;

FIG. 2B is a side view of the semiconductor power module package shown in FIG. 2A;

FIG. 2C is a cross-sectional view of the semiconductor power module package shown in FIG. 2A taken from along a line IIC-IIC;

FIG. 2D is a cross-sectional view of the semiconductor power module package shown in FIG. 2B in which the external bonding lead is wire-bonded to an external circuit substrate by an external wire; and

FIG. 3 is a cross-sectional view of a semiconductor power module package according to still another embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements, and thus their description will be omitted.

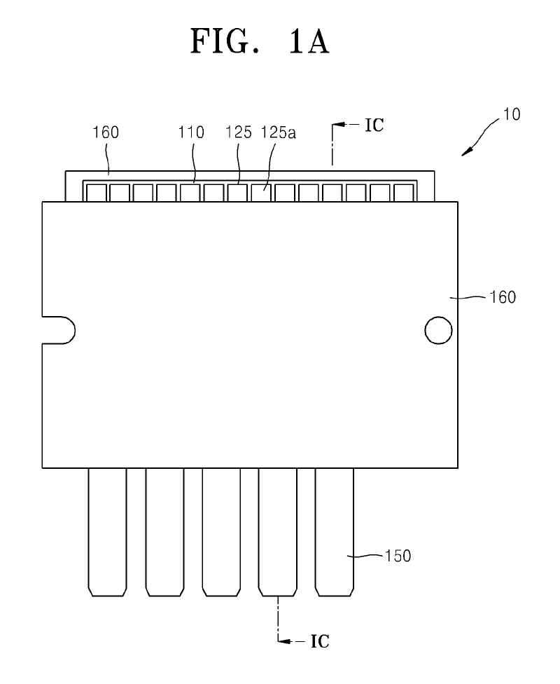

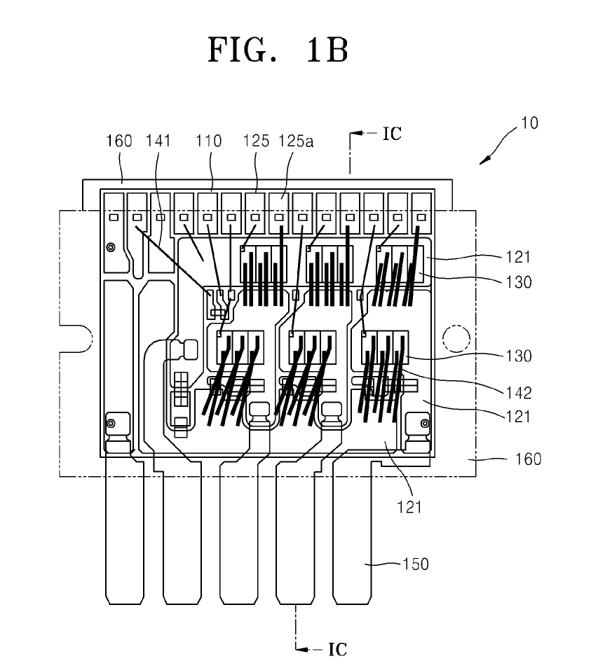

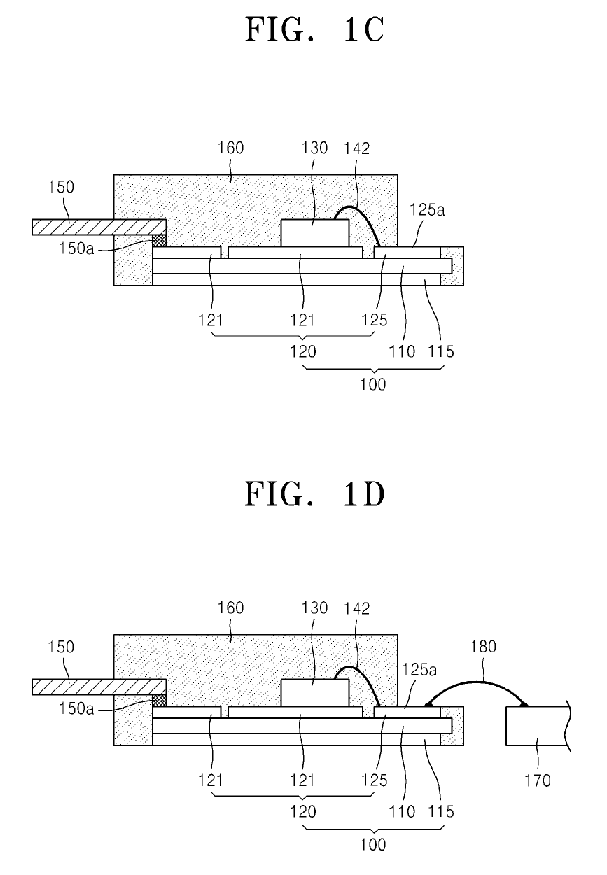

FIG. 1A is a plan view of a semiconductor power module package 10 according to an embodiment of the present invention. FIG. 1B is a plan view of the semiconductor power module package 10 shown in FIG. 1A before being molded. FIG. 1C is a cross-sectional view of the semiconductor power module package 10 shown in FIG. 1A taken from along a line IC-IC. FIG. 1D is a cross-sectional view of the semiconductor power module package 10 shown in FIG. 1C that is wire-bonded to an external circuit board 170 through an external bonding area of a direct bonding cupper (DBC) substrate.

Referring to FIGS. 1A through 1D, the semiconductor power module package 10 comprises a packaging substrate 100 and a plurality of semiconductor chips 130 disposed on the packaging substrate 100. The packaging substrate 100 may include the DBC substrate. The packaging substrate 100 may comprise a ceramic insulation film 110, an upper conductive film 120 disposed on the upper surface of ceramic insulation film 110, and a lower conductive film 115 disposed on the lower surface of the ceramic insulation film 110.

The ceramic insulation film 110 may include an Al₂O₃film, an AlN film, a SiO₂ film, a Si₃N₄ film or a BeO film. The upper conductive film 120 and the lower conductive film 115 may include a Cu film. The upper conductive film 120 and the lower conductive film 115 may include the Cu film plated with one selected from a group consisting of Ni, Au, and Ag or a bare Cu film.

The upper conductive film 120 may include first and second conductive film patterns 121 and 125 that are electrically separate from each other. A plurality of semiconductor chips 130 may be disposed on some of the first conductive film patterns 121. The semiconductor chips 130 may include power semiconductor chips and/or control semiconductor chips. The semiconductor chips 130 may be adhered onto the first conductive film patterns 121 by a solder (not shown) or an adhesive member (not shown) such as Au epoxy.

The semiconductor chips 130 may be electrically connected to the first and second conductive film patterns 121 and 125 by a plurality of second wires 142. A plurality of leads 150 may be attached to the first conductive film patterns 121 by a solder 150a. The second conductive film patterns 125 may be wire-bonded to the semiconductor chips 130 and the first conductive film patterns 121 by a plurality of first wires 141. The first wires 141 may include wires having a width of 6 mm. The second wires 142 may include wires having a width of 12 mm relatively greater than the first wires 141.

A sealing member 160 is formed on the upper and side surfaces of the packing substrate 100 having the first and second conductive film patterns 121 and 125 to cover the semiconductor chips 130 and the first and second wires 141 and 142. The sealing member 160 may be formed to partially expose the upper surface of the packaging substrate 100 including portions 125a of the second conductive film patterns 125. The sealing member 160 may include a transfer molded epoxy molding compound (EMC).

The portions 125a of the second conductive film patterns 125 may act as an external bonding area. Thus, the external bonding area 125a is wire-bonded to a bonding pad (not shown) of the external circuit board 170 so that the semiconductor chips 130 can be electrically connected to the external circuit board 170. The external bonding area 125a may be disposed on the packing substrate 100 to face the leads 150.

The leads 150 are used to provide the semiconductor chips 130 with power signals. The external bonding area 125a is used to provide the semiconductor chips 130 with a signal such as a control signal. A heat sink (not shown) may be attached onto the lower conductive film 115 to dissipate heat generated from the semiconductor chips 130.

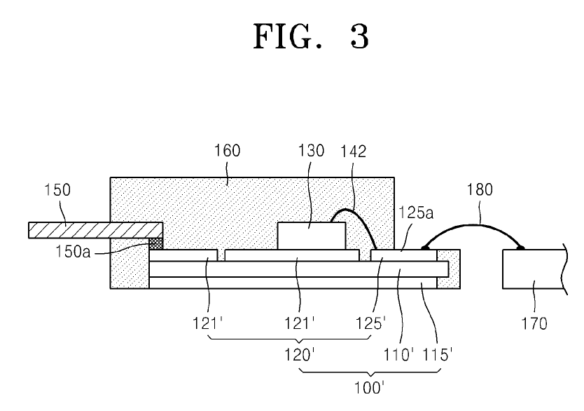

FIG. 3 is a cross-sectional view of a semiconductor power module package according to still another embodiment of the present invention.

In FIGS. 3 and 1D, like numerals designate like elements, and the descriptions of some elements may not be repeated. The packaging substrate 100′ may be an insulated metal substrate (IMS) comprising a insulation epoxy film 110′, an upper conductive film pattern 120′ disposed on the upper surface of a insulation epoxy film 110′, and a lower conductive film 115′ disposed on the lower surface of the a insulation epoxy film 110′. The thickness of the insulation epoxy film 110′ may be about 20 to 200 μm.

The lower conductive film 115′ may include a conductive metal film composed of Al, Cu, Fe or Zn film. The upper conductive film pattern 120′ may include the first and second conductive film patterns 121′ and 125′. The first and second conductive film patterns 121′ and 125′ may include a Cu film plated with one selected from a group consisting of Ni, Au, or Ag and a bare Cu film and may include a Al film plated with Cu partially for soldering and plated one selected from a group consisting of Ni, Au, or Ag on a Cu plated.

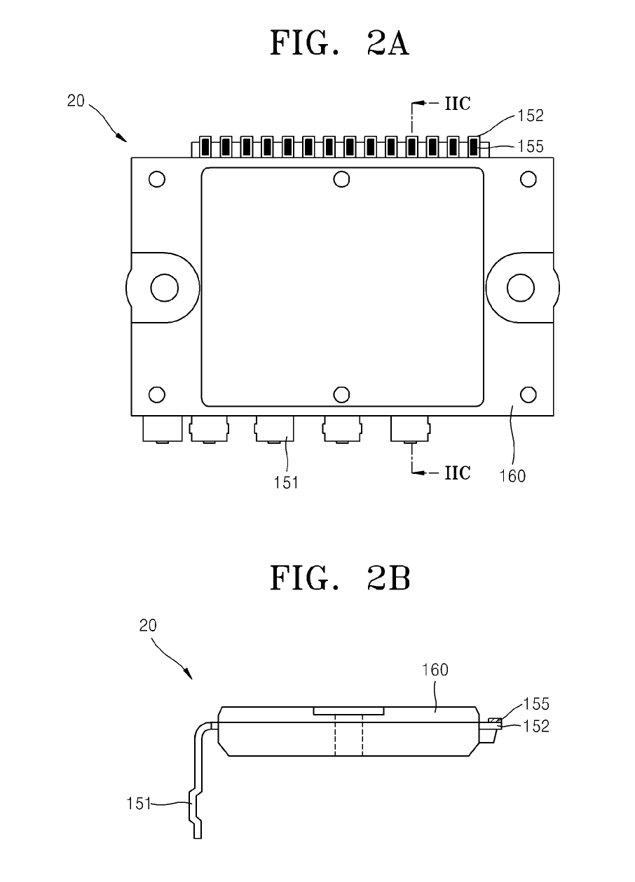

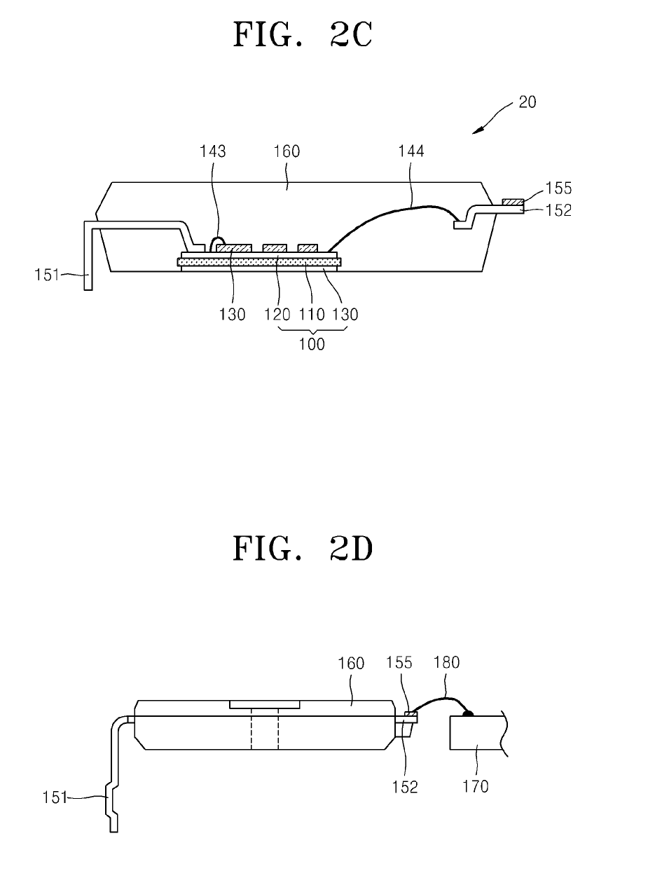

FIG. 2A is a plan view of a semiconductor power module package 20 according to another embodiment of the present invention. FIG. 2B is a side view of the semiconductor power module package 20 shown in FIG. 2A. FIG. 2C is a cross-sectional view of the semiconductor power module package 20 shown in FIG. 2A taken from along a line IIC-IIC. FIG. 2D is a cross-sectional view of the semiconductor power module package 20 shown in FIGS. 2A through 2C that is wire-bonded to an external circuit board 170.

Referring to FIGS. 2A through 2D, the semiconductor power module package 20 comprises a packaging substrate 100 and a plurality of semiconductor chips 130 disposed on the packaging substrate 100. The packaging substrate 100 may include a DBC substrate including a ceramic insulation film 110 and an upper conductive film 120 and a lower conductive film 130 that are disposed on the upper surface and the lower surface of the ceramic insulation film 110, respectively. The upper conductive film 120 may include first and second conductive film patterns 121 and 125 that are electrically separated from each other. The semiconductor chips 130 may be disposed on the first conductive film patterns 121. Alternatively, the packaging substrate 100 may include an IMS substrate.

The semiconductor chips 130 may include power semiconductor chips and/or control semiconductor chips. The semiconductor chips 130 may be adhered onto the upper conductive film 120 of the packaging substrate 100 by a solder (not shown) or an adhesive member (not shown) such as Au epoxy. The semiconductor chips 130 may be electrically connected to the upper conductive film 120 by a wire 143.

A plurality of leads 151 may be electrically connected to the upper conductive film 120 by a solder (corresponding to the solder 150a). The leads 151 may include power leads. The semiconductor power module package 20 may further include a plurality of external bonding leads 152 that are electrically connected to the upper conductive film 120 of the packaging substrate 110. The external bonding leads 152 are used for external wire bonding and may include signal leads. The external bonding leads 152 and the leads 151 may include one selected from a group consisting of a Ni plated Cu film, a P containing Ni plated Cu film, an Ag plated Cu film, and a bare Cu film.

A sealing member 160 is formed on the upper and side surfaces of the packaging substrate 100 including the semiconductor chips 130 so that the leads 151 and the external bonding leads 152 are partially exposed. The sealing member 160 may include a transfer molded EMC.

A plurality of external bumps 155 may be further disposed on portions of the external bonding leads 152 that are exposed from the sealing member 160. The external bumps 155 may include Al bumps. The external bumps 155 may have widths of 20 mm. The external bonding leads 152 or the Al bumps 155 may be wire-bonded to bonding pads (not shown) of the external circuit board 170 by an external wire 180. The external wire 180 may include one selected from a group consisting of an Al wire, an Ag wire, and a Cu wire. The external wire 180 may have a width of 8 mm.

The semiconductor power module packages 10 and 20 shown in FIGS. 1A through 2D may have various types of package structures.

The semiconductor power module package according to the present invention includes an additional bonding area that is wire-bonded to an external circuit board that is exposed from a sealing member, which does not need an additional lead frame area for soldering or wire bonding, thereby reducing the package size and package manufacturing costs. The wire connection between the semiconductor power module package and the external circuit board by the wire-bonding can increase reliability of a joint and productivity of the semiconductor power module package since flexibility of a wire prevents a failure of the joint due to a physical vibration or a solder crack.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor power module package comprising:
one or more semiconductor chips;
a sealing member sealing the one or more semiconductor chips;
a plurality of leads electrically connected to the one or more semiconductor chips and exposed from the sealing member; and
an external bonding member electrically connected to the one or more semiconductor chips and electrically connecting an external circuit board exposed from the sealing member.

2. The semiconductor power module package of claim 1, further comprising: a packaging substrate including electrically separated conductive film patterns,
wherein first conductive film patterns of the conductive film patterns are electrically connected to the plurality of leads.

3. The semiconductor power module package of claim 2, wherein the external bonding member includes a plurality of external bonding areas for wire-bonding to the external circuit board and disposed on the packaging substrate and exposed from the sealing member.

4. The semiconductor power module package of claim 3, wherein the plurality of external bonding areas include the portions of second conductive film patterns of the conductive film patterns exposed from the sealing member.

5. The semiconductor power module package of claim 4, wherein the first and second conductive film patterns include a Cu film plated with one selected from a group consisting of Ni, Au, or Ag and a bare Cu film.

6. The semiconductor power module package of claim 3, wherein a plurality of power signals are provided to the one or more semiconductor chips via the plurality of leads, and a plurality of control signals are provided to the one or more semiconductor chips via the plurality of external bonding areas.

7. The semiconductor power module package of claim 2, wherein the plurality of external bonding areas include a plurality of external bonding leads that are partially exposed from the sealing member.

8. The semiconductor power module package of claim 7, wherein the plurality of leads and the plurality of external bonding leads include one selected from a group consisting of Ni plated Cu leads, P containing Ni plated Cu leads, Ag plated Cu leads, or bare Cu leads.

9. The semiconductor power module package of claim 8, wherein the external bonding member further includes a plurality of external bumps disposed on the plurality of external bonding leads exposed from the sealing member.

10. The semiconductor power module package of claim 9, wherein the plurality of external bumps include Al bumps.

11. The semiconductor power module package of claim 7, wherein the plurality of leads include power leads, and the plurality of external bonding leads include signal leads.

12. The semiconductor power module package of claim 2, wherein the one or more semiconductor chips are disposed on some of the first conductive film patterns.

13. The semiconductor power module package of claim 2, wherein the packaging substrate includes a direct bonding cupper (DBC) substrate or an insulated metal substrate(IMS).

14. The semiconductor power module package of claim 1, wherein the sealing member includes a transfer molded epoxy molding compound (EMC).

15. The semiconductor power module package of claim 1, wherein the external bonding member is wire-bonded to the external circuit board by an external wire.

16. The semiconductor power module package of claim 15, wherein the external wire includes one selected from a group consisting of an Al wire, an Ag wire, and a Cu wire.

17. A semiconductor power module package comprising:
an insulation substrate including one or more electrically separated conductive film patterns;
a plurality of semiconductor chips on a plurality of first conductive film patterns of the one or more conductive film patterns;
a sealing member formed on the upper and side surfaces of the insulation substrate and sealing the plurality of semiconductor chips and the one or more conductive film patterns; and
a plurality of leads electrically connected to the plurality of semiconductor chips and exposed from the sealing member,
wherein a plurality of second conductive film patterns of the conductive film patterns that are not disposed on the plurality of semiconductor chips include a plurality of external bonding areas that are electrically connected to an external circuit board and is exposed from the sealing member.

18. The semiconductor power module package of claim 17, wherein the plurality of leads include power leads,
wherein the plurality of external bonding areas are electrically connected to the external circuit board by an external wire, and transfer signals between the plurality of semiconductor chips and the external circuit board.

19. The semiconductor power module package of claim 18, wherein the external wire includes one selected from a group consisting of an Al wire, an Ag wire, and a Cu wire.

20. The semiconductor power module package of claim 17, wherein the first and second conductive film patterns include a Cu film plated with one selected from a group consisting of Ni, Au, or Ag and a bare Cu film.
